(19) United States
(12) Patent Application Publication
(10) Pub. No.: US 2021/0360827 A1
(43) Pub. Date: Nov. 18, 2021

(54) HEAT DISSIPATION STRUCTURE FOR DISPLAY PANEL, AND MANUFACTURING METHOD AND APPLICATION THEREOF

(71) Applicant: WUHAN CHINA STAR OPTOELECTRONICS SEMICONDUCTOR DISPLAY TECHNOLOGY CO., LTD., Wuhan (CN)

(72) Inventor: Yijia Wang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/623,671

(22) PCT Filed: Sep. 29, 2019
(86) PCT No.: PCT/CN2019/108979

§ 371 Date: Dec. 17, 2019

(30) Foreign Application Priority Data
Jul. 30, 2019 (CN) 201910694407.1

(51) Int. Cl. H05K 7/20

(52) U.S. Cl. CPC H05K 7/20481; H05K 7/20954

(57) ABSTRACT

Provided are a heat dissipation structure for a display panel, and a manufacturing method and an application thereof. The heat dissipation structure includes a copper foil layer and a heat conducting layer disposed on the copper foil layer; wherein a material of the heat conducting layer includes a heat conducting material having a three-dimensional structure, and a gap in the three-dimensional structure of the heat conducting material is filled with a buffer.

### FIELD OF THE INVENTION

The present invention relates to a display panel field, and more particularly to a heat dissipation structure for a display panel, and a manufacturing method and an application thereof.

### BACKGROUND OF THE INVENTION

Flexible OLED displays are popular in the display industry due to their low power consumption, high resolution, fast response and bendability. As the thickness thereof is thinner, the market competitiveness of the display can be greater. At present, a flexible material, such as polyimide film (PI) or polyethylene terephthalate (PET) is often used as a substrate. A thin film transistor (TFT), an OLED and a thin film encapsulation (TFE) are sequentially formed on the substrate, and then a polarizer and a glass cover plate are bonded thereon. In order to drive the TFT, it is necessary to bond a chip circuit at the bottom of the flexible substrate to constitute a display panel.

When the display is functioning, the current will heat up through the TFT circuit. In order to facilitate heat dissipation, a heat dissipation structure is generally disposed under the PI. Please refer to FIG. 1. FIG. 1 is a structural diagram of a heat dissipation structure in the prior art. The heat dissipation structure includes a copper foil layer 1, a graphite layer 2 and a buffer layer 3 which are sequentially disposed. However, the thickness of the three-in-one structure is large, and the graphite layer 20 is a sheet structure, and heat is mainly conducted along the direction of the sheet, so the heat dissipation effect of the display screen is not ideal.

In the prior art, there is a heat dissipation structure in which a slurry prepared by mixing graphene and metal particles is used as a heat conduction layer. However, the method of particle coating cannot ensure continuous thermal contact between the particles and the lower layer. The internal heat conduction meshwork is incomplete, and the heat transfer effect in the vertical direction is poor, and the manufacturing method has defects.

Therefore, there is a need to develop a novel heat dissipation structure for a display panel to overcome the drawbacks of the prior art.

### SUMMARY OF THE INVENTION

An objective of the present invention is to provide a heat dissipation structure for a display panel, which can solve the problem that the heat dissipation effect of the display panel in the prior art is poor and the thickness of the panel is thick.

For realizing the aforesaid objective, the present invention provides a heat dissipation structure for a display panel, including a copper foil layer and a heat conducting layer disposed on the copper foil layer; wherein a material of the heat conducting layer includes a heat conducting material having a three-dimensional structure, and a gap in the three-dimensional structure of the heat conducting material is filled with a buffer.

Furthermore, in other embodiments, the three-dimensional structure of the heat conducting material is a tree-like three-dimensional structure, and a material of the heat conducting material includes one of a porous carbon and a carbon fiber meshwork. This arrangement establishes more thermal diffusion channels, and the heat of the display panel can be quickly conducted along various paths and directly transmitted to the copper foil layer, which greatly shortens the heat conduction path. Moreover, as a part of the longitudinal heat conduction channels is damaged, the heat can also quickly find a proper channel in the plane, and then the longitudinal conduction remains to shorten the heat conduction path and to improve the heat dissipation effect.

Furthermore, in other embodiments, the three-dimensional structure of the heat conducting material is a longitudinal three-dimensional structure, and the heat conducting layer includes a first one-dimensional heat conducting layer and a first two-dimensional heat conducting layer disposed in sequence, and the first one-dimensional heat conducting layer and the first two-dimensional heat conducting layer are hybridized to form the longitudinal three-dimensional structure.

Furthermore, in other embodiments, a material of the first one-dimensional heat conducting layer includes one of longitudinal nanotubes or longitudinal nano-pillars.

Furthermore, in other embodiments, a material of the first two-dimensional heat conducting layer includes a longitudinal nanowall.

Furthermore, in other embodiments, a number of the first one-dimensional heat conducting layers is two or more; and a number of the first two-dimensional heat conducting layers is two or more.

Furthermore, in other embodiments, a material of the buffer includes an acrylic material or a PU (polyurethane) material. In other embodiments, the buffer can also be made of other elastic polymers. The elastic polymer has good elasticity and flexibility and acts to buffer the stress of the longitudinal or tree-like heat conducting material. Meanwhile, the buffer is directly filled into the gap of the heat conducting material to reduce the thickness of the heat dissipation structure, thereby reducing the overall thickness of the display panel.

Furthermore, in other embodiments, a thickness range of the heat conducting layer is from 50 μm to 150 μm.

Another objective of the present invention is to provide a manufacturing method of a heat dissipation structure for a display panel, including steps of:

Step S1, providing a copper foil layer, and manufacturing a heat conducting layer on the copper foil layer; and

Step S2, filling a buffer in the heat conducting layer.

Furthermore, in other embodiments, Step S1 of manufacturing the heat conducting layer on the copper foil layer includes: directly depositing the heat conducting material having the three-dimensional structure to form the heat conducting layer on the copper foil layer by one of plasma enhanced chemical vapor deposition, atomic layer deposition and pulsed laser deposition.

Furthermore, in other embodiments, Step S1 of manufacturing the heat conducting layer on the copper foil layer includes: manufacturing the heat conducting material having the three-dimensional structure to form the heat conducting layer on the copper foil layer by one of a template method and a hydrothermal method.

Another objective of the present invention is to provide a display panel, including a substrate layer, a light emitting layer, an encapsulation layer and a cover plate disposed in sequence, wherein the heat dissipation structure of the present invention is disposed under the substrate layer.

Compared with the prior art, the benefit of the present invention is to provide a heat dissipation structure for a display panel, and a manufacturing method and an application thereof. First, the sheet structural and laterally heat conducting graphite layer is replaced by a three-dimensional heat-conductive heat conducting layer, and more thermal diffusion channels are established. The heat of the display panel can be quickly conducted along various paths and directly transmitted to the copper foil layer, which greatly shortens the heat conduction path. Moreover, as a part of the longitudinal heat conduction channels is damaged, the heat can also quickly find a proper channel in the plane, and then the longitudinal conduction remains to shorten the heat conduction path and to improve the heat dissipation effect. Meanwhile, the buffer is directly filled into the gap of the heat conducting material having the three-dimensional structure to change the three-in-one structure in the prior art into a two-layer composite structure, which can reduce the thickness of the heat dissipation structure, thereby reducing the overall thickness of the display panel.

### BRIEF DESCRIPTION OF THE DRAWINGS

In order to more clearly illustrate the embodiments of the present invention, the following figures will be described in the embodiments are briefly introduced. It is obvious that the drawings are merely some embodiments of the present invention, those of ordinary skill in this field can obtain other figures according to these figures without paying the premise.

FIG. 1 is a structural diagram of a heat dissipation structure in the prior art;

FIG. 2 is a structural diagram of a heat dissipation structure according to embodiment 1 of the present invention;

FIG. 3 is a structural diagram of a display panel according to embodiment 1 of the present invention;

FIG. 4 is a structural diagram of a heat dissipation structure according to embodiment 2 of the present invention; and

FIG. 5 is a structural diagram of a display panel according to embodiment 2 of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

The specific structural and functional details disclosed here are merely representative and are used for the purpose of describing exemplary embodiments of the invention. However, the present invention may be embodied in many alternative forms and should not be construed as being limited only to the embodiments set forth herein.

### Embodiment 1

The embodiment provides a heat dissipation structure for a display panel. Please refer to FIG. 2. FIG. 2 is a structural diagram of a heat dissipation structure according to the present embodiment of the present invention. The heat dissipation structure includes a copper foil layer 1 and a heat conducting layer 2 disposed on the copper foil layer 1. A thickness range of the heat conducting layer is from 50 μm to 150 μm.

A material of the heat conducting layer 2 includes a heat conducting material 21 having a three-dimensional structure. In this embodiment, the three-dimensional structure of the heat conducting material 21 is a tree-like three-dimensional structure, and a material of the heat conducting material is a porous carbon. In other embodiments, a material of the heat conducting material 21 may also be a carbon fiber meshwork, and is not limited here.

The tree-like three-dimensional structure heat conducting material 21 establishes more thermal diffusion channels, and the heat of the display panel can be quickly conducted along various paths and directly transmitted to the copper foil layer 1, which greatly shortens the heat conduction path. Moreover, as a part of the longitudinal heat conduction channels is damaged, the heat can also quickly find a proper channel in the plane, and then the longitudinal conduction remains to shorten the heat conduction path and to improve the heat dissipation effect.

The buffer 22 is filled in the gap of the tree-like three-dimensional structure heat conducting material 21. In this embodiment, the material used for the buffer 22 is an acrylic material. The acrylic material is an elastic polymer with good elasticity and flexibility, and acts for buffering the stress applied to the tree-like three-dimensional structure heat conducting material. Meanwhile, the buffer 22 is directly filled into the gap of the heat conducting material 21 to reduce the thickness of the heat dissipation structure, thereby reducing the overall thickness of the display panel.

In other embodiments, the buffer 22 can also be made of a PU material or other elastic polymers, which is not limited herein.

The present embodiment further provides a manufacturing method of the aforesaid heat dissipation structure, including steps of:

Step S1, providing a copper foil layer, and manufacturing a heat conducting layer on the copper foil layer.

Manufacturing the heat conducting layer can be directly depositing the heat conducting material having the three-dimensional structure to form the heat conducting layer by one of plasma enhanced chemical vapor deposition, atomic layer deposition and pulsed laser deposition.

In other embodiments, the heat conducting material having the three-dimensional structure can be manufactured to form the heat conducting layer by one of a template method and a hydrothermal method.

Step S2, filling a buffer in the heat conducting layer.

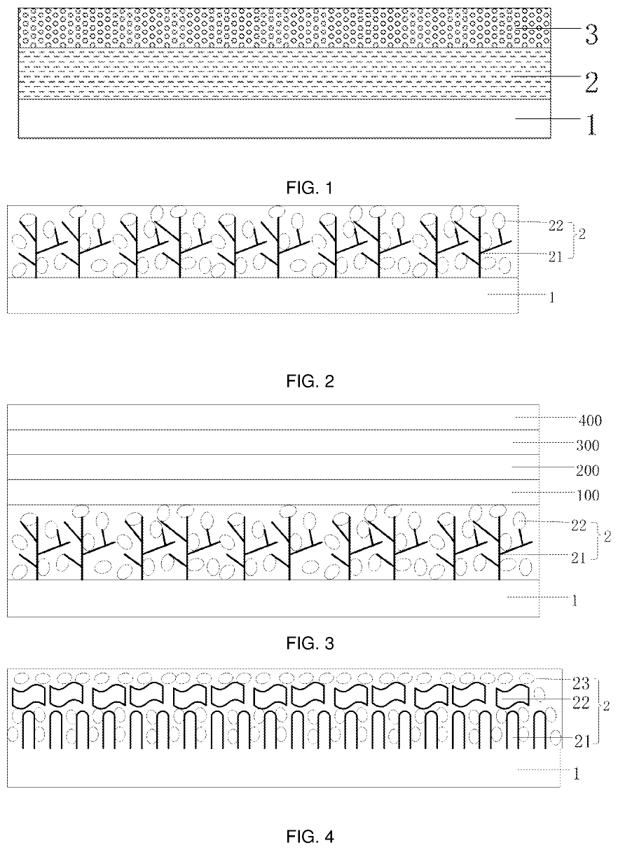

This embodiment further provides a display panel. Please refer to FIG. 3. FIG. 3 is a structural diagram of a display panel according to this embodiment of the present invention. The display panel includes a substrate layer 100, a light emitting layer 200, an encapsulation layer 300 and a cover plate 400 disposed in sequence. The aforesaid heat dissipation structure is disposed under the substrate layer 100.

The present embodiment provides a heat dissipation structure for a display panel, and a manufacturing method and an application thereof. First, the sheet structural and laterally heat conducting graphite layer is replaced by a three-dimensional heat-conductive heat conducting layer, and more thermal diffusion channels are established. The heat of the display panel can be quickly conducted along various paths and directly transmitted to the copper foil layer, which greatly shortens the heat conduction path. Moreover, as a part of the longitudinal heat conduction channels is damaged, the heat can also quickly find a proper channel in the plane, and then the longitudinal conduction remains to shorten the heat conduction path and to improve the heat dissipation effect. Meanwhile, the buffer is directly filled into the gap of the heat conducting material to change the three-in-one structure in the prior art into a two-layer composite structure, which can reduce the thickness of the heat dissipation structure, thereby reducing the overall thickness of the display panel.

### Embodiment 2

The embodiment provides a heat dissipation structure for a display panel. Please refer to FIG. 4. FIG. 4 is a structural diagram of a heat dissipation structure according to the present embodiment of the present invention. The heat dissipation structure includes a copper foil layer 1 and a heat conducting layer 2 disposed on the copper foil layer 1. A thickness range of the heat conducting layer is from 50 μm to 150 μm.

The heat conducting layer 2 includes a one-dimensional heat conducting layer 21 and a two-dimensional heat conducting layer 22, and the one-dimensional heat conducting layer 21 and the two-dimensional heat conducting layer 22 are hybridized to form a longitudinal three-dimensional structure. A material of the one-dimensional heat conducting layer 21 is longitudinal nanotubes, and a material of the two-dimensional heat conducting layer 22 is a longitudinal nanowall.

In other embodiments, the material of the one-dimensional heat conducting layer 21 may also be longitudinal nano-pillars and is not limited herein.

The longitudinal three-dimensional structure heat conducting layer 2 establishes more thermal diffusion channels. The heat of the display panel can be quickly conducted along various paths and directly transmitted to the copper foil layer 1, which greatly shortens the heat conduction path and improves the heat dissipation effect.

In other embodiments, a number of the one-dimensional heat conducting layers 21 is two or more; and a number of the two-dimensional heat conducting layers 22 is two or more.

The buffer 23 is filled in the gap of the longitudinal three-dimensional structure heat conducting material. In this embodiment, the material used for the buffer 23 is an acrylic material. The acrylic material is an elastic polymer with good elasticity and flexibility, and acts for buffering the stress applied to the longitudinal three-dimensional structure heat conducting material. Meanwhile, the buffer 23 is directly filled into the gap of the heat conducting material to reduce the thickness of the heat dissipation structure, thereby reducing the overall thickness of the display panel.

In other embodiments, the buffer 23 can also be made of a PU material or other elastic polymers, which is not limited herein.

The present embodiment further provides a manufacturing method of the aforesaid heat dissipation structure, including steps of:

Step S1, providing a copper foil layer, and manufacturing a heat conducting layer on the copper foil layer.

Manufacturing the heat conducting layer can be directly depositing the heat conducting material having the three-dimensional structure to form the heat conducting layer by one of plasma enhanced chemical vapor deposition, atomic layer deposition and pulsed laser deposition.

In other embodiments, the heat conducting material having the three-dimensional structure can be manufactured to form the heat conducting layer by one of a template method and a hydrothermal method.

Step S2, filling a buffer in the heat conducting layer.

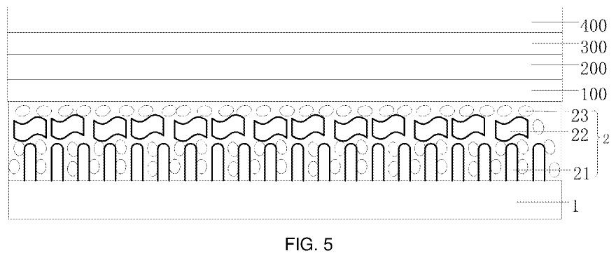

This embodiment further provides a display panel. Please refer to FIG. 5. FIG. 5 is a structural diagram of a display panel according to this embodiment of the present invention. The display panel includes a substrate layer 100, a light emitting layer 200, an encapsulation layer 300 and a cover plate 400 disposed in sequence. The aforesaid heat dissipation structure is disposed under the substrate layer 100.

The present embodiment provides a heat dissipation structure for a display panel, and a manufacturing method and an application thereof. First, the sheet structural and laterally heat conducting graphite layer is replaced by a three-dimensional heat-conductive heat conducting layer, and more thermal diffusion channels are established. The heat of the display panel can be quickly conducted along various paths and directly transmitted to the copper foil layer, which greatly shortens the heat conduction path and improves the heat dissipation effect. Meanwhile, the buffer is directly filled into the gap of the heat conducting material to change the three-in-one structure in the prior art into a two-layer composite structure, which can reduce the thickness of the heat dissipation structure, thereby reducing the overall thickness of the display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A heat dissipation structure for a display panel, including a copper foil layer and a heat conducting layer disposed on the copper foil layer; wherein a material of the heat conducting layer includes a heat conducting material having a three-dimensional structure, and a gap in the three-dimensional structure of the heat conducting material is filled with a buffer.

2. The heat dissipation structure according to claim 1, wherein the three-dimensional structure of the heat conducting material is a tree-like three-dimensional structure, and a material of the heat conducting material includes one of a porous carbon and a carbon fiber meshwork.

3. The heat dissipation structure according to claim 1, wherein the three-dimensional structure of the heat conducting material is a longitudinal three-dimensional structure, and the heat conducting layer includes a first one-dimensional heat conducting layer and a first two-dimensional heat conducting layer disposed in sequence, and the first one-dimensional heat conducting layer and the first two-dimensional heat conducting layer are hybridized to form the longitudinal three-dimensional structure.

4. The heat dissipation structure according to claim 3, wherein a material of the first one-dimensional heat conducting layer includes one of longitudinal nanotubes or longitudinal nano-pillars.

5. The heat dissipation structure according to claim 3, wherein a material of the first two-dimensional heat conducting layer includes a longitudinal nanowall.

6. The heat dissipation structure according to claim 1, wherein a material of the buffer includes an acrylic material or a PU (polyurethane) material.

7. A manufacturing method of the heat dissipation structure for the display panel according to claim 1, including steps of:
Step S1, providing a copper foil layer, and manufacturing a heat conducting layer on the copper foil layer; and
Step S2, filling a buffer in the heat conducting layer.

8. The manufacturing method according to claim 7, wherein Step S1 of manufacturing the heat conducting layer on the copper foil layer includes: directly depositing the heat conducting material having the three-dimensional structure to form the heat conducting layer on the copper foil layer by one of plasma enhanced chemical vapor deposition, atomic layer deposition and pulsed laser deposition.

9. The manufacturing method according to claim 7, wherein Step S1 of manufacturing the heat conducting layer on the copper foil layer includes: manufacturing the heat conducting material having the three-dimensional structure to form the heat conducting layer on the copper foil layer by one of a template method and a hydrothermal method.

10. The manufacturing method according to claim 7, wherein the three-dimensional structure of the heat conducting material is a tree-like three-dimensional structure, and a material of the heat conducting material includes one of a porous carbon and a carbon fiber meshwork.

11. The manufacturing method according to claim 7, wherein the three-dimensional structure of the heat conducting material is a longitudinal three-dimensional structure, and the heat conducting layer includes a first one-dimensional heat conducting layer and a first two-dimensional heat conducting layer disposed in sequence, and the first one-dimensional heat conducting layer and the first two-dimensional heat conducting layer are hybridized to form the longitudinal three-dimensional structure.

12. The manufacturing method according to claim 7, wherein a material of the first one-dimensional heat conducting layer includes one of longitudinal nanotubes or longitudinal nano-pillars.

13. The manufacturing method according to claim 7, wherein a material of the first two-dimensional heat conducting layer includes a longitudinal nanowall.

14. The manufacturing method according to claim 7, wherein a material of the buffer includes an acrylic material or a PU (polyurethane) material.

15. A display panel, including a substrate layer, a light emitting layer, an encapsulation layer and a cover plate disposed in sequence, wherein the heat dissipation structure according to claim 1 is disposed under the substrate layer.

16. The display panel according to claim 15, wherein the three-dimensional structure of the heat conducting material is a tree-like three-dimensional structure, and a material of the heat conducting material includes one of a porous carbon and a carbon fiber meshwork.

17. The display panel according to claim 15, wherein the three-dimensional structure of the heat conducting material is a longitudinal three-dimensional structure, and the heat conducting layer includes a first one-dimensional heat conducting layer and a first two-dimensional heat conducting layer disposed in sequence, and the first one-dimensional heat conducting layer and the first two-dimensional heat conducting layer are hybridized to form the longitudinal three-dimensional structure.

18. The display panel according to claim 17, wherein a material of the first one-dimensional heat conducting layer includes one of longitudinal nanotubes or longitudinal nano-pillars.

19. The display panel according to claim 17, wherein a material of the first two-dimensional heat conducting layer includes a longitudinal nanowall.

20. The display panel according to claim 15, wherein a material of the buffer includes an acrylic material or a PU (polyurethane) material.
